(19) United States
(12) Patent Application Publication
(10) Pub. No.: US 2025/0104997 A1
(43) Pub. Date: Mar. 27, 2025

(54) METHOD OF PROCESSING SUBSTRATE, METHOD OF MANUFACTURING SEMICONDUCTOR DEVICE, RECORDING MEDIUM AND SUBSTRATE PROCESSING APPARATUS

(71) Applicant: Kokusai Electric Corporation, Tokyo (JP)

(72) Inventors: Tomoki IMAMURA, Toyama-shi (JP); Yoshitomo HASHIMOTO, Toyama-shi (JP); Takaaki NODA, Toyama-shi (JP); Kazuyuki OKUDA, Toyama-shi (JP); Kazuhiro HARADA, Toyama-shi (JP)

(73) Assignee: Kokusai Electric Corporation, Tokyo (JP)

(21) Appl. No.: 18/883,544

(22) Filed: Sep. 12, 2024

(30) Foreign Application Priority Data
Sep. 21, 2023 (JP) 2023-156532

(51) Int. Cl. H01L 21/02

(52) U.S. Cl. CPC H01L 21/02115

(57) ABSTRACT

There is provided a technique that includes: (a) forming an intermediate layer containing carbon on a first film formed on a substrate; and (b) forming a second film containing nitrogen on the intermediate layer by using an activated nitrogen-containing gas, wherein in (a), the intermediate layer is formed such that a carbon content per unit area in the intermediate layer differs between a central region and an outer region in a substrate plane of the substrate.

### CROSS-REFERENCE TO RELATED APPLICATION

This application is based upon and claims the benefit of priority from Japanese Patent Application No. 2023-156532, filed on Sep. 21, 2023, the entire contents of which are incorporated herein by reference.

### TECHNICAL FIELD

The present disclosure relates to a method of processing a substrate, a method of manufacturing a semiconductor device, a recording medium and a substrate processing apparatus.

### BACKGROUND

In the related art, as a process of manufacturing a semiconductor device, a process of supplying a processing gas to a substrate to form a film on the substrate may be performed.

However, when forming a film, properties such as an etching resistance and the like may be changed near an interface between a base and the film. It is sometimes desired that occurrences of the change in the properties be suppressed, or that even when a layer with changed properties (hereinafter referred to as a “transition layer”) is formed, a thickness distribution of the layer in a plane of the substrate be controlled.

### SUMMARY

Some embodiments of the present disclosure provide a technique capable of suppressing an occurrence of a change in properties such as an etching resistance and the like occurring near an interface between a base and a film when the film is formed, or capable of controlling a thickness distribution of a transition layer in a plane of a substrate even when the transition layer is formed.

According to embodiments of the present disclosure, there is provided a technique that includes: (a) forming an intermediate layer containing carbon on a first film formed on a substrate; and (b) forming a second film containing nitrogen on the intermediate layer by using an activated nitrogen-containing gas, wherein in (a), the intermediate layer is formed such that a carbon content per unit area in the intermediate layer differs between a central region and an outer region in a substrate plane of the substrate.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, and is a diagram showing a portion of the process furnace a vertical cross-sectional view.

FIG. 2 is a schematic configuration diagram of the vertical process furnace of the substrate processing apparatus suitably used in the embodiments of the present disclosure, and is a diagram showing a portion of the process furnace in a cross-sectional view taken along line A-A in FIG. 1.

FIG. 3 is a schematic configuration diagram of a controller of the substrate processing apparatus suitably used in the embodiments of the present disclosure, and is showing a control system of the controller in a block diagram.

FIG. 4 is a flowchart showing a substrate processing process suitably used in the embodiments of the present disclosure.

FIGS. 5A and 5B are diagrams showing an example of a cross-sectional structure of a film formed on a substrate.

FIGS. 6A and 6B are diagrams showing a cross-sectional structure of a film formed on a substrate according to a modification.

FIG. 7 is a diagram showing evaluation results of an etching resistance of a film formed on a substrate.

FIG. 8 is a diagram showing evaluation results of an etching resistance in a central region and an outer region in a plane of a film formed on a substrate.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### Embodiments of the Present Disclosure

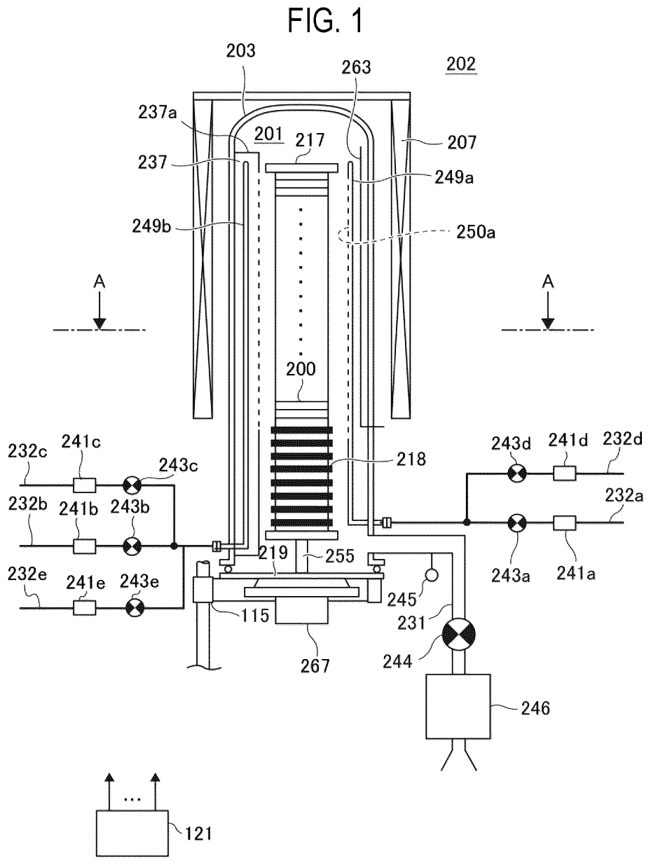

Embodiments of the present disclosure are described below mainly with reference to FIGS. 1 to 5B. The drawings used in the following description are schematic. The dimensional relationships of respective elements, the ratios of respective elements, and the like shown in the drawings may not match the actual ones. Further, the dimensional relationships of respective elements, the ratios of respective elements, and the like may not match among a plurality of drawings.

### (1) Configuration of Substrate Processing Apparatus

As shown in FIG. 1, the process furnace 202 includes a heater 207 as a heating system (temperature adjuster). The heater 207 also functions as an activator (exciter) that activates (excites) a gas with heat as to be described later.

Inside the heater 207, a reaction tube 203 constituting a reaction container (process container) is disposed concentrically with the heater 207. The reaction tube 203 is formed in a cylindrical shape with a closed upper end and an opened lower end. A process chamber 201 is formed in a cylindrical hollow region of the reaction tube 203. The process chamber 201 is configured to be able to accommodate wafers 200 as substrates in a state in which the wafers 200 are arranged in a horizontal posture and in multiple stages in a vertical direction by a boat 217 to be described later.

In the process chamber 201, nozzles 249a and 249b are provided to penetrate through a lower portion of the reaction tube 203. Gas supply pipes 232a and 232b are connected to the nozzles 249a and 249b, respectively. A gas supply pipe 232c is connected to the gas supply pipe 232b. In this way, two nozzles 249a and 249b and three gas supply pipes 232a to 232c are provided in the reaction tube 203 so that multiple types of gases may be supplied into the process chamber 201.

On the gas supply pipes 232a to 232c, mass flow controllers (MFC) 241a to 241c, which are flow rate controllers (flow rate control parts), and valves 243a to 243c, which are opening/closing valves, are respectively provided in order from an upstream side. A gas supply pipe 232d for supplying an inert gas is connected to the gas supply pipe 232a on a downstream side than the valve 243a. Furthermore, a gas supply pipe 232e for supplying an inert gas is connected to a downstream side of a connection portion between the gas supply pipe 232b and the gas supply pipe 232c. On the gas supply pipes 232d and 232e, MFCs 241d and 241e and valves 243d and 243e are respectively provided in order from an upstream side.

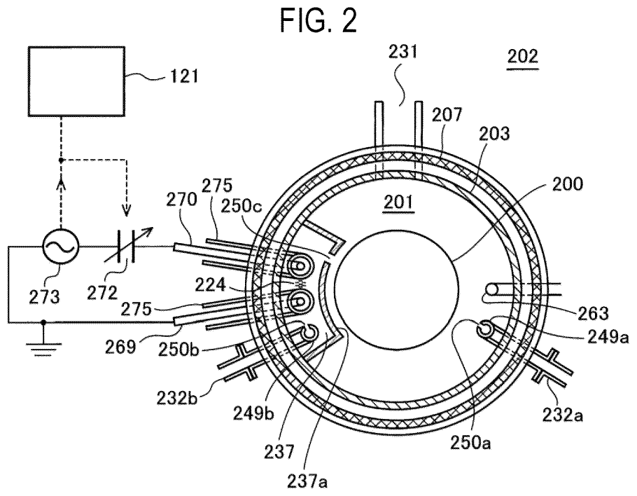

A nozzle 249a is connected to a tip of the gas supply pipe 232a. As shown in FIG. 2, the nozzle 249a is provided in a space of an annular shape in a plane view between an inner wall of the reaction tube 203 and the wafers 200, so as to extend upward in a stacking direction of the wafers 200 from a lower portion to an upper portion of the inner wall of the reaction tube 203. Gas supply holes 250a for supplying a gas are provided on a side surface of the nozzle 249a. The gas supply holes 250a are opened toward a center of the reaction tube 203, enabling supply of a gas toward the wafers 200. The gas supply holes 250a are provided in plural over a region from a lower portion to an upper portion of the reaction tube 203. The respective gas supply holes 250a possess the same opening area, and are provided at the same opening pitch.

A nozzle 249b is connected to a tip of the gas supply pipe 232b. The nozzle 249b is provided within a buffer chamber 237, which is a gas dispersion space. The buffer chamber 237 is formed between the inner wall of the reaction tube 203 and a partition wall 237a. As shown in FIG. 2, the buffer chamber 237 (partition wall 237a) is provided in a space of an annular shape in a plane view between the inner wall of the reaction tube 203 and the wafers 200, and in a region extending from the lower portion to the upper portion of the inner wall of the reaction tube 203 so as to extend along the stacking direction of the wafers 200. Gas supply holes 250c for supplying a gas is provided at an end of a surface of the partition wall 237a facing (adjacent to) the wafers 200. The gas supply holes 250c are opened toward the center of the reaction tube 203, enabling supply of a gas toward the wafers 200. The gas supply holes 250c are provided in plural over a region from the lower portion to the upper portion of the reaction tube 203. The respective gas supply holes 250c possess the same opening area, and are provided at the same opening pitch.

The nozzle 249b is provided at an end of the buffer chamber 237 opposite to the end where the gas supply holes 250c are provided, so as to extend upward in the stacking direction of the wafers 200 from the lower portion to the upper portion of the inner wall of the reaction tube 203. Gas supply holes 250b for supplying a gas is provided on a side surface of the nozzle 249b. The gas supply holes 250b are opened toward a center of the buffer chamber 237. The gas supply holes 250b are provided in plural over a region from the lower portion to the upper portion of the reaction tube 203, just like the gas supply holes 250c. The gas injected into the buffer chamber 237 from the gas supply holes 250b is injected into the process chamber 201 from the gas supply holes 250c.

As described above, in the embodiments, a gas is transported via the nozzles 249a and 249b and the buffer chamber 237 disposed in a cylindrical space. Then, the gas is injected into the reaction tube 203 from the gas supply holes 250a to 250c for the first time in the vicinity of the wafers 200. A main flow of the gas within the reaction tube 203 is formed in a direction parallel to surfaces of the wafers 200, i.e., in a horizontal direction. The gas flowing on the surfaces of the wafers 200, i.e., the gas remaining after reaction, flows toward an exhaust port, i.e., an exhaust pipe 231, which is described later.

From the gas supply pipe 232a, a precursor gas containing a predetermined element, for example, a precursor gas containing silicon (Si) as a predetermined element and a halogen element, is supplied into the process chamber 201 through the MFC 241a and the valve 243a.

From the gas supply pipe 232b, a nitrogen (N)-containing gas as a nitriding gas is supplied into the process chamber 201 through the MFC 241b and the valve 243b.

As the nitriding gas, an N-containing gas activated by plasma excitation may be used. Further, as the nitriding gas, an N-containing gas activated by thermal excitation without using plasma excitation (i.e., by non-plasma excitation) may also be used.

From the gas supply pipe 232c, a carbon (C)-and nitrogen (N)-containing gas is supplied into the process chamber 201 through the MFC 241c and the valve 243c. The C- and N-containing gas may also be regarded as a C-containing gas.

From the gas supply pipes 232d and 232e, an inert gas is supplied into the process chamber 201 through the MFCs 241d and 241e and the valves 243d and 243e, respectively.

A precursor gas supply system is mainly constituted by the gas supply pipe 232a, the MFC 241a, and the valve 243a. The nozzle 249a may be included in the precursor gas supply system. The precursor gas supply system may also be referred to as a precursor supply system.

Further, an N-containing gas supply system is mainly constituted by the gas supply pipe 232b, the MFC 241b, and the valve 243b. The nozzle 249b and the buffer chamber 237 may be included in the N-containing gas supply system. The N-containing gas supply system may also be referred to as a nitriding gas supply system or a nitriding agent supply system.

Further, a C- and N-containing gas supply system is mainly composed of the gas supply pipe 232c, the MFC 241c, and the valve 243c. The downstream side of the connection portion between the gas supply pipe 232b and the gas supply pipe 232c, the nozzle 249b, and the buffer chamber 237 may be included in the C-and N-containing gas supply system. The C- and N-containing gas supply system may also be regarded as a C-containing gas supply system.

Any of or the entire above-mentioned precursor gas, N-containing gas, and C- and N-containing gas may also be referred to as a processing gas. Further, any of or the entire precursor gas supply system, N-containing gas supply system, and C- and N-containing gas supply system may also be referred to as a processing gas supply system, or simply a supply system.

Further, an inert gas supply system is mainly constituted by the gas supply pipes 232d and 232e, the MFCs 241d and 241e, and the valves 243d and 243e. The inert gas supply system may also be referred to as a purge gas supply system or a carrier gas supply system.

Inside the buffer chamber 237, as shown in FIG. 2, two rod-shaped electrodes 269 and 270 made of a conductor and formed in an elongated structure extend from the lower portion to the upper portion of the reaction tube 203 along the direction in which the wafers 200 are arranged. Each of the rod-shaped electrodes 269 and 270 is provided parallel to the nozzle 249b. Each of the rod-shaped electrodes 269 and 270 is protected by being covered from an upper portion to a lower portion by an electrode protection tube 275. One of the rod-shaped electrodes 269 and 270 is connected to a radio-frequency power source 273 through a matching box 272, and the other is connected to the ground, which is a reference potential. Plasma is generated in a plasma generation region 224 between the rod-shaped electrodes 269 and 270 by applying radio-frequency (RF) power from the radio-frequency power source 273 to between the rod-shaped electrodes 269 and 270. A plasma source as a plasma generator (plasma generation part) is mainly constituted by the rod-shaped electrodes 269 and 270, and the electrode protection tube 275. The matching box 272 and the radio-frequency power source 273 may be included in the plasma source. As described later, the plasma source functions as a plasma exciter (activator) that excites (activates) a gas into a plasma state.

The reaction tube 203 is provided with an exhaust pipe 231 that exhausts the atmosphere inside the process chamber 201. A vacuum pump 246 as a vacuum exhauster is connected to the exhaust pipe 231 through a pressure sensor 245 as a pressure detector (pressure detection part) that detects a pressure inside the process chamber 201 and an APC (Auto Pressure Controller) valve 244 as a pressure regulator (pressure regulation part). The APC valve 244 is configured to perform vacuum-exhaust of an inside of the process chamber 201 or stop the vacuum-exhaust by being opened and closed while the vacuum pump 246 is in operation, and is configured to regulate the pressure inside the process chamber 201 by adjusting a valve opening state based on pressure information detected by the pressure sensor 245 while the vacuum pump 246 is in operation. An exhaust system is mainly constituted by the exhaust pipe 231, the APC valve 244, and the pressure sensor 245. The vacuum pump 246 may be included in the exhaust system.

A seal cap 219 is provided below the reaction tube 203 as a furnace opening lid that is capable of airtightly closing a lower end opening of the reaction tube 203. A rotator 267 for rotating a boat 217, which is described later, is installed on an opposite side of the seal cap 219 with respect to the process chamber 201. The rotary shaft 255 of the rotator 267 is connected to the boat 217, and is configured to rotate the wafers 200 by rotating the boat 217. A boat elevator 115 serving as an elevator installed vertically outside the reaction tube 203 is configured to be capable of loading and unloading the boat 217 into and out of the process chamber 201 by raising and lowering the seal cap 219.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with each other. That is, the boat 217 is configured to arrange the wafers 200 to be spaced apart from each other. At a lower portion of the boat 217, heat insulating plates 218 are supported in a horizontal posture at multiple stages.

A temperature sensor 263 as a temperature detector is installed inside the reaction tube 203. A temperature in the process chamber 201 is set to achieve a desired temperature distribution by regulating a state of electric power supplied to the heater 207 based on temperature information detected by the temperature sensor 263.

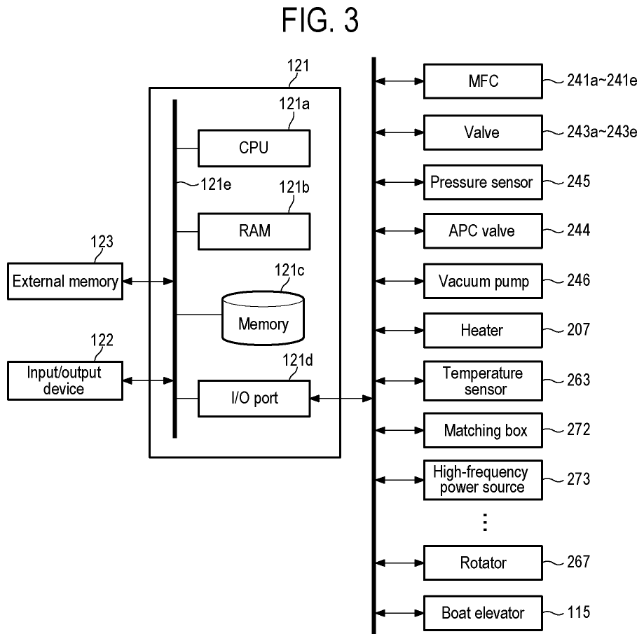

As shown in FIG. 3, the controller 121, which is a control part (control means), is configured as a computer including a CPU (Central Processing Unit) 121a, a RAM (Random Access Memory) 121b, a memory 121c, and an I/O port 121d. The RAM 121b, the memory 121c, and the I/O port 121d are configured to be capable of exchanging data with the CPU 121a via an internal bus 121e. An input/output device 122 configured as, for example, a touch panel or the like is connected to the controller 121. Further, an external memory 123 may be connected to the controller 121. The substrate processing apparatus may be configured to include one controller, or may be configured to include a plurality of controllers. That is, control for performing a processing sequence to be described later may be performed using one controller, or may be performed using a plurality of controllers. Further, the plurality of controllers may be configured as a control system by being connected to each other through a wired or wireless communication network, and the entire control system may perform control for performing the processing sequence described below. When the term “controller” is used herein, it may include one controller, a plurality of controllers, or a control system configured by a plurality of controllers.

The memory 121c is composed of, for example, a flash memory, a HDD (Hard Disk Drive), and the like. The memory 121c stores, in a readable manner, control programs for controlling operations of the substrate processing apparatus, process recipes in which procedures, conditions, etc. of substrate processing to be described later are written, and the like. The process recipes are combinations of instructions that cause the controller 121 to execute each procedure in a substrate processing process described later to obtain a predetermined result. The process recipes function as programs. Hereinafter, the process recipes, the control programs, and the like may also be collectively and simply referred to as “programs.” Further, the process recipes may also be simply referred to as “recipes.” The term “programs” as used herein may refer to a case of including the recipes, a case of including the control programs, or a case of including both. The RAM 121b is configured as a memory area (work area) in which programs, data, and the like read by the CPU 121a are temporarily held.

The I/O port 121d is connected to the MFCs 241a to 241e, the valves 243a to 243e, the pressure sensor 245, the APC valve 244, the vacuum pump 246, the heater 207, the temperature sensor 263, the rotator 267, the boat elevator 115, the matching box 272, the radio-frequency power source 273, and the like.

The CPU 121a is configured to read a control program from the memory 121c and execute the control program, and is configured to read a process recipe from the memory 121c in response to an input of an operation command and the like from the input/output device 122. The CPU 121a is configured to, according to contents of the process recipe thus read, control the flow rate regulating operations of various gases by the MFC 241a to 241e, the opening and closing operations of the valves 243a to 243e, the opening and closing operation of the APC valve 244, the pressure regulating operation by the APC valve 244 based on the pressure sensor 245, the startup and shutdown of the vacuum pump 246, the temperature regulating operation of the heater 207 based on the temperature sensor 263, the rotation and rotational speed adjusting operation of the boat 217 by the rotator 267, the raising and lowering operation of the boat 217 by the boat elevator 115, the impedance regulating operation by the matching box 272, the power supply to the radio-frequency power source 273, and the like.

The controller 121 may be configured by installing, on a computer, the above-mentioned programs stored in the external memory 123 (e.g., a magnetic tape, a magnetic disk such as a flexible disk or a hard disk, an optical disk such as a CD or a DVD, a magneto-optical disk such as an MO, or a semiconductor memory such as a USB memory or a memory card). The memory 121c and the external memory 123 are configured as computer-readable recording media. Hereinafter, these are collectively and simply referred to as “recording medium.” When the term “recording medium” is used herein, it may refer to a case of including the memory 121c, a case of including the external memory 123, or a case of including both. The program may be provided to the computer using communication means such as the Internet or a dedicated line without using the external memory 123.

### (2) Substrate Processing Process

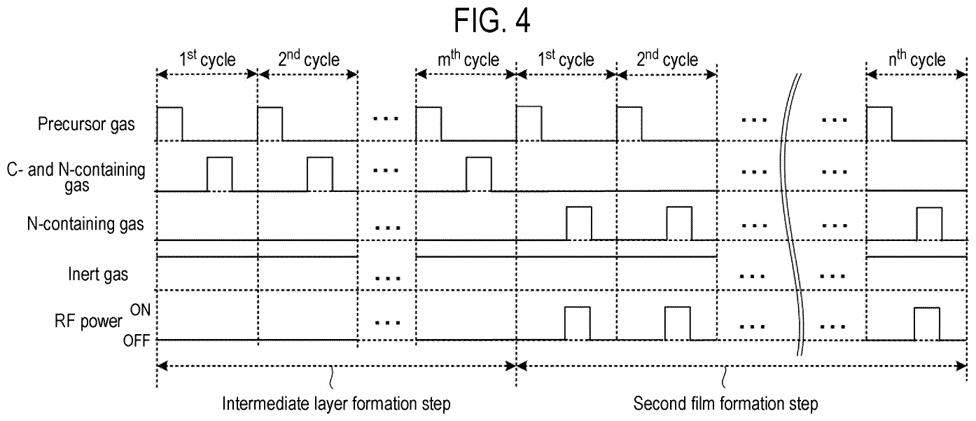

An example of a sequence in which a second film is formed on the wafer 200 on which a first film is formed as a base is described with reference to FIG. 4 as a process of manufacturing a semiconductor device using the above-described substrate processing apparatus. In the following description, the operation of each part included in the substrate processing apparatus is controlled by the controller 121.

A substrate processing sequence shown in FIG. 4 includes: (a) forming an intermediate layer containing carbon (C) and nitrogen (N), or an intermediate layer containing C but not containing N, on a first film formed on a wafer 200 serving as a substrate (intermediate layer formation step); and (b) forming a second film containing N on the intermediate layer by using an activated N-containing gas (second film formation step). In this specification, the intermediate layer containing C and N and the intermediate layer containing C but not containing N may be collectively referred to as an intermediate layer containing C.

In the present disclosure, the substrate processing sequence shown in FIG. 4 may be expressed as follows for the sake of convenience. In the present disclosure, the N-containing gas activated by plasma excitation is referred to as N-containing gas* for the sake of convenience. Similar notations are used in the following description of modifications.

(precursor gas→C- and N-containing gas)×m→(precursor gas→N-containing gas*)×n=>second film/intermediate layer

The term “wafer” used herein may refer to “a wafer itself” or “a stacked including a wafer and a predetermined layer or film formed on a surface of a wafer.” The term “a surface of a wafer” used herein may refer to “a surface of a wafer itself” or “a surface of a predetermined layer or the like formed on a wafer.” The expression “a predetermined layer is formed on a wafer” used herein may mean that “a predetermined layer is directly formed on a surface of a wafer itself” or that “a predetermined layer is formed on a layer or the like formed on a wafer.” The term “substrate” used herein may be synonymous with the term “wafer.”

### (Wafer Charging and Boat Loading)

A plurality of wafers 200 are charged onto the boat 217 (wafer charging). Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the reaction tube 203.

An oxide film as the first film is formed in advance on at least a portion of the surface of the wafer 200. This film becomes at least a portion of a base film when forming the intermediate layer in the intermediate layer formation step described later. The oxide film may be formed to cover the entire surface of the wafer 200, or may be formed to cover a portion thereof. Examples of the oxide film include a Si-containing film such as a silicon oxide film (SiO film), a silicon oxynitride film (SiON film), a silicon oxycarbide film (SiOC film), a silicon oxycarbonitride film (SiOCN film) or the like, and a metal oxide film, i.e., a high dielectric constant insulating film (high-k film) such as an aluminum oxide film (AlO film), a hafnium oxide film (HfO film), a zirconium oxide film (ZrO film), a titanium oxide film (TiO film) or the like. The oxide film (the oxynitride film, the oxycarbide film, or the oxycarbonitride film) mentioned herein may include, for example, an oxide film that is intentionally formed by performing a predetermined process such as a CVD process, a plasma CVD process, a thermal oxidation process, or a plasma oxidation process, and a natural oxide film that is naturally formed when the wafer 200 is exposed to the atmosphere during transfer or the like. However, the first film is not limited to the oxide film, and may be any other film in which a transition layer may be formed between itself and the second film, which is described later. In addition, the first film is not limited to the film formed on the surface of the wafer 200, and the surface of the wafer 200 itself may constitute the first film as the base film.

### (Pressure Regulation and Temperature Regulation)

The vacuum pump 246 performs vacuum-exhaust (pressure reduction exhaust) so that the pressure in the process chamber 201, i.e., the pressure in the space where the wafers 200 exist, reaches a desired pressure (degree of vacuum). At this time, the pressure inside the process chamber 201 is measured by the pressure sensor 245, and the APC valve 244 is feedback-controlled based on the pressure information measured. The vacuum pump 246 is kept in an operating state at least until the process on the wafers 200 is completed. Further, the wafers 200 in the process chamber 201 are heated by the heater 207 to a desired temperature. Moreover, the rotation of the boat 217 and the wafers 200 by the rotator 267 is initiated. The rotation of the boat 217 and the wafers 200 by the rotator 267 continues at least until the process on the wafers 200 is completed.

### (Intermediate Layer Formation Step)

Thereafter, the next two steps, namely step S1a and step S1b, are executed.

### [Step S1a]

In this step, a precursor gas is supplied to the wafers 200 in the process chamber 201.

Specifically, the valve 243a is opened and the precursor gas is allowed to flow into the gas supply pipe 232a. A flow rate of the precursor gas is regulated by the MFC 241a. The precursor gas is then supplied into the process chamber 201 via the nozzle 249a, and is exhausted from the exhaust pipe 231. At this time, the precursor gas is supplied to the wafers 200. At the same time, the valve 243d is opened to allow an inert gas to flow into the gas supply pipe 232d. A flow rate of the inert gas is regulated by the MFC 241d. The inert gas is then supplied into the process chamber 201 together with the precursor gas, and is exhausted from the exhaust pipe 231.

That is, in this step, the precursor gas is supplied toward a central region within a substrate plane, and the inert gas is supplied together with the precursor gas toward a central regions of the wafers 200.

A processing condition when supplying the precursor gas in this step is exemplified as follows.
Processing temperature: 250 to 700 degrees C., specifically 300 to 650 degrees C., more specifically 350 to 600 degrees C.
Processing pressure: 1 to 2,666 Pa, specifically 67 to 1,333 Pa
Precursor gas supply flow rate: 1 to 2,000 sccm, specifically 10 to 1,000 sccm
Precursor gas supply time: 1 to 120 seconds, specifically 1 to 60 seconds
Inert gas supply flow rate (each nozzle): 100 to 10,000 sccm
   From the viewpoint of improving a processing speed, it is particularly preferable that the processing temperature remains substantially the same in the entire steps of the intermediate layer formation step.

In the present disclosure, the notation of a numerical range such as “250 to 700 degrees C.” means that a lower limit and an upper limit are included in the range. Therefore, for example, “250 to 700 degrees C.” means “250 degrees C. or more and 700 degrees C. or less.” The same applies to other numerical ranges. In the present disclosure, the processing temperature means the temperature of the wafers 200 or the temperature inside the process chamber 201, and the processing pressure means the pressure inside the process chamber 201. Further, a processing time means the time during which a process is continued. The same applies to the following description.

By supplying the precursor gas to the wafer 200 under the above condition, a first layer, containing a predetermined element and with a thickness of, for example, less than one atomic layer to several atomic layers, is formed on the wafer 200 (the base film including the first film on the surface). For example, when a gas containing Si and Cl is used as the precursor gas, a Si-containing layer containing Cl is formed as the first layer. In addition, O contained in the first film serving as the base may be incorporated into the first layer. In the present disclosure, the first layer containing Cl and O (Si-containing layer containing O and Cl) may also be simply referred to as a Si-containing layer for the sake of convenience.

After the first layer is formed, the valve 243a is closed to stop supplying the precursor gas. At this time, the APC valve 244 is kept opened to vacuum-exhaust the process chamber 201 by the vacuum pump 246, and any unreacted precursor gas or any precursor gas after contributing to the formation of the first layer, which remains in the process chamber 201, is removed from the inside of the process chamber 201. At this time, the valves 243d and 243e are kept opened to maintain the supply of the inert gas into the process chamber 201. The inert gas acts as a purge gas.

As the precursor gas, an inorganic halosilane precursor gas such as a hexachlorodisilane (Si₂Cl₆) gas, a monochlorosilane (SiH₃Cl) gas, a dichlorosilane (SiH₂Cl₂) gas, a trichlorosilane (SiHCl₃) gas, a tetrachlorosilane (SiCl₄) gas, an octachlorotrisilane (Si₃Cl₈) gas or the like may be used.

In addition, as the precursor gas, an alkylenehalosilane precursor gas such as an ethylenebis(trichlorosilane) gas, a 1,2-bis(trichlorosilyl)ethane ((SiCl₃)₂C₂H₄) gas, a bis(trichlorosilyl)methane ((SiCl₃)₂CH₂) gas or the like may be used.

In addition, as the precursor gas, an alkylhalosilane precursor gas such as a 1,1,2,2-tetrachloro-1,2-dimethyldisilane ((CH₃)₂Si₂Cl₄) gas, a 1,2-dichloro-1,1,2,2-tetramethyldisilane ((CH₃)₄Si₂Cl₂) gas, a 1-monochloro-1,1,2,2,2-pentamethyldisilane ((CH₃)₅Si₂Cl) gas or the like may be used.

In addition, as the precursor gas, an inorganic precursor gas such as a monosilane (SiH₄) gas, a disilane (Si₂H₆) gas, a trisilane (Si₃H₈) gas or the like may be used.

In addition, as the precursor gas, for example, an aminosilane precursor gas such as a tetrakisdimethylaminosilane (Si[N(CH₃)₂]₄) gas, a trisdimethylaminosilane (Si[N(CH₃)₂]₃H) gas, a bisdiethylaminosilane (Si[N(C₂H₅)₂]₂H₂) gas, a bis-tertiary-butylaminosilane (SiH₂[NH(C₄H₉)]₂) gas or the like may be used.

As the precursor gas, one or more of the above-mentioned gases may be used.

As the inert gas, in addition to the nitrogen (N₂) gas, for example, a rare gas such as an argon (Ar) gas, a helium (He) gas, a neon (Ne) gas, a xenon (Xe) gas or the like may be used. One or more of these gases may be used as the inert gas. The same applies to the inert gas in the following description.

### [Step S1b]

After step S1a is completed, a C- and N-containing gas is supplied to the wafers 200 in the process chamber 201, i.e., the first layer formed on the first film 300.

Specifically, the valve 243c is opened to allow the C- and N-containing gas to flow into the gas supply pipe 232c. A flow rate of the C- and N-containing gas is regulated by the MFC 241c. The C- and N-containing gas is then supplied into the process chamber 201 via the gas supply pipe 232b, the nozzle 249b, and the buffer chamber 237, and is exhausted from the exhaust pipe 231. At this time, the C- and N-containing gas is supplied to the wafers 200. At the same time, the valve 243e is opened to allow an inert gas to flow into the gas supply pipe 232e. A flow rate of the inert gas is regulated by the MFC 241e. The inert gas is then supplied into the process chamber 201 together with the C- and N-containing gas.

That is, in this step, the C- and N-containing gas is supplied toward the central region in the substrate plane, and the inert gas is supplied together with the C- and N-containing gas toward the central regions of the wafers 200.

A processing condition when supplying the C- and N-containing gas in this step is exemplified as follows.
Processing pressure: 1 to 5,000 Pa, specifically 1 to 4,000 Pa
C- and N-containing gas supply flow rate: 100 to 10,000 sccm
C- and N-containing gas supply time: 1 to 200 seconds, specifically 1 to 120 seconds, more specifically 1 to 60 seconds
   Other processing conditions may be the same as those used when supplying the precursor gas.

By supplying the C- and N-containing gas to the wafer 200 under the above condition, the first layer formed on the wafer 200 in step S1a may react with the C- and N-containing gas. Specifically, for example, Cl (chloro group), which is a halogen element (halogen group) contained in the first layer, and C-containing ligands contained in the C- and N-containing gas may react with each other. Thus, at least a portion of the Cl contained in the first layer is extracted (separated) from the first layer, and at least a portion of the C-containing ligands contained in the C- and N-containing gas is separated from the C- and N-containing gas. The C-containing ligand is, for example, an alkyl group such as an ethyl group or a methyl group composed of C and hydrogen (H). Then, N in the C- and N-containing gas from which at least a portion of the C-containing ligands is separated may be bonded to Si contained in the first layer to form a Si—N bond. At this time, it is also possible to bond C contained in the C-containing ligand separated from the C- and N-containing gas to Si contained in the first layer to form a Si—C bond. As a result, Cl is desorbed from the first layer, and an N component is newly incorporated into the first layer. At this time, a C component is also newly incorporated into the first layer.

By supplying the C- and N-containing gas under the above condition, the first layer and the C- and N-containing gas may be caused to react appropriately, enabling the series of reactions described above to occur. Through this series of reactions, the N component and the C component are newly incorporated into the first layer, and the first layer is changed (modified) into a layer containing a predetermined element, C, and N. Specifically, for example, the first layer is changed to a silicon carbonitride layer (SiCN layer) serving as a second layer. This layer may also be referred to as a C-containing SiN layer. The second layer possesses a thickness of less than one atomic layer to about several atomic layers. Further, the second layer is a layer in which a proportion of the Si component and a proportion of the C component are relatively large, i.e., a layer which is rich in Si and rich in C.

After the second layer is formed, the valve 243c is closed to stop the supply of the C-and N-containing gas. Then, any unreacted C- and N-containing gas or any C- and N-containing gas after contributing to the formation of the second layer, and any reaction by-products, which remain in the process chamber, are removed from the process chamber 201 by the same processing procedure as in step S1a.

As the C- and N-containing gas, for example, an organic hydrazine-based gas, an amine-based gas or the like may be used.

As the organic hydrazine-based gas, a methylhydrazine-based gas such as a monomethylhydrazine ((CH₃)HN₂H₂) gas, a dimethylhydrazine ((CH₃)₂N₂H₂) gas, a trimethylhydrazine ((CH₃)₂N₂(CH₃)H) gas or the like may be used. Further, as the organic hydrazine-based gas, an ethylhydrazine-based gas such as an ethylhydrazine ((C₂H₅)HN₂H₂) gas or the like may be used.

As the amine-based gas, for example, an ethylamine-based gas such as a triethylamine ((C₂H₅)₃N) gas, a diethylamine ((C₂H₅)₂NH) gas, a monoethylamine (C₂H₅NH₂) gas or the like may be used. Further, as the amine-based gas, a methylamine-based gas such as a trimethylamine ((CH₃)₃N) gas, a dimethylamine ((CH₃)₂NH) gas, a monomethylamine (CH₃NH₂) gas or the like may be used. Further, as the amine-based gas, a propylamine-based gas such as a tripropylamine ((C₃H₇)₃N) gas, a dipropylamine ((C₃H₇)₂NH) gas, a monopropylamine (C₃H₇NH₂) gas or the like may be used. Further, as the amine-based gas, an isopropylamine-based gas such as a triisopropylamine ([(CH₃)₂CH]₃N) gas, a diisopropylamine ([(CH₃)₂CH]₂NH) gas, a monoisopropylamine ((CH₃)₂CHNH₂) gas or the like may be used. Further, as the amine-based gas, a butylamine-based gas such as a tributylamine ((C₄H₉)₃N) gas, a dibutylamine ((C₄H₉)₂NH) gas, a monobutylamine (C₄H₉NH₂) gas or the like may be used. In addition, as the amine-based gas, an isobutylamine-based gas such as a triisobutylamine ([(CH₃)₂CHCH₂]₃N) gas, a diisobutylamine ([(CH₃)₂CHCH₂]₂NH) gas, a monoisobutylamine ((CH₃)₂CHCH₂NH₂) gas or the like may be used.

That is, as the amine-based gas, for example, one or more gases of (C₂H₅)ₓNH₃₋ₓ, (CH₃)ₓNH₃₋ₓ, (C₃H₇)ₓNH₃₋ₓ, [(CH₃)₂CH]ₓNH₃₋ₓ, (C₄H₉)ₓNH₃₋ₓ, and [(CH₃)₂CHCH₂]ₓNH₃₋ₓ (where x is an integer of 1 to 3) may be used.

As the C- and N-containing gas, one or more of the above-mentioned gases may be used.

### (Performing a Predetermined Number of Times)

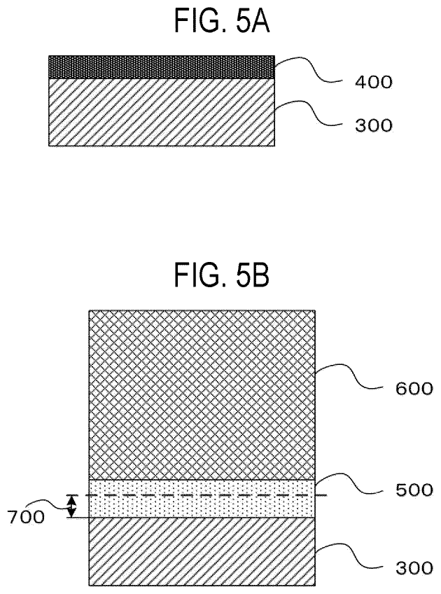

A cycle of performing the above-mentioned steps S1a and S1b non-simultaneously, i.e., without synchronization, is performed m times or more (where m is an integer greater than or equal to 1). Thus, as shown in FIG. 5A, an intermediate layer 400 containing a predetermined element, C and N may be formed on the first film 300 formed on the wafer 200. That is, the intermediate layer 400 contains the predetermined element other than C and N. As the intermediate layer 400, for example, a SiCN layer containing Si as the predetermined element, C, and N may be formed. The intermediate layer 400 may also be referred to as a seed layer. In step S1b, by using a C-containing gas that does not contain N in place of the C- and N-containing gas, a layer containing C but not containing N (e.g., a SiC layer) may be formed as the intermediate layer 400.

In order to explain effects of forming the intermediate layer 400 between the first film 300 and the second film 600, a case where a nitride film as the second film 600 is directly formed on an oxide film as the first film 300 is described first.

When the second film 600 is directly formed on the first film 300, oxygen (O), which is an element contained in the first film 300, may diffuse into the second film 600 which does not substantially contain O. Due to this diffusion of O, a layer (O diffusion layer) containing O in addition to the predetermined element and N is formed among the second film 600 at an interface with the first film 300. Since this O diffusion layer contains O, the etching rate thereof is different (i.e., the etching resistance thereof is different) from that of the second film 600. In other words, near the interface between the second film 600 and the first film 300, there is formed a transition layer whose etching rate is varied (changed) in a thickness direction from the second film 600 to the first film 300 depending on an O diffusion concentration or the like.

The transition layer possesses a gradient of O content concentration such that the closer it is to the first film 300, the higher the O content concentration is, and the farther away from the first film 300, the lower the O content concentration is. The etching rate of the transition layer is also varied according to the gradient of the O content concentration. More specifically, for example, when an etching agent (e.g., a hydrogen fluoride (HF) gas, a diluted aqueous HF solution, etc.) with a high etching rate for the oxide film as the first film 300 and a low etching rate for the nitride film as the second film 600 is used, a layer in which the etching rate is varied to increase in the thickness direction toward the first film 300 is formed in a portion of the second film 600.

For example, when it is desired to selectively remove the first film 300 with respect to the second film 600 by an etching process, at least a portion of the transition layer with a higher etching rate (lower etching resistance) than the second film 600 may be etched in addition to the first film targeted to be etched, resulting in a decrease in etching controllability. Therefore, when forming the second film 600, it may be needed to suppress the formation of such a transition layer or to reduce a thickness of the transition layer to be formed.

According to the technique of the present disclosure, an intermediate layer 400 containing C is formed on the first film 300 in advance. When the second film 600 is formed on the intermediate layer 400, at least a portion of C contained in the intermediate layer 400 diffuses into the vicinity of the interface of the second film 600. Specifically, as shown in FIG. 5B, in the vicinity of the interface between the intermediate layer 400 and the second film 600, a C-containing diffusion layer 500 is formed during the formation of the second film 600 due to the diffusion of C into the second film 600. The diffusion layer 500 possesses a gradient of C content concentration such that the closer it is to the first film 300, the higher the C content concentration is, and the farther away from the first film 300, the lower the C content concentration is. In this regard, the C element contained in the intermediate layer 400 acts to reduce an etching rate (increase an etching resistance) of the portion of the second film 600 where C is diffused. Therefore, C in the diffusion layer 500 acts to reduce the etching rate heavily as it is closer to the first film 300, and acts to reduce the etching rate lightly as it is farther away from the first film 300.

As described above, the increase in the etching rate due to the O diffused from the first film 300 tends to become larger as a distance from the first film 300 grows smaller, and tends to become smaller as the distance from the first film 300 grows larger, depending on the gradient of the O content concentration. Therefore, by forming the diffusion layer 500 with a gradient of the C content concentration similar to that of the O content concentration when forming the second film 600, it is possible to suppress the formation of the transition layer resulted from O diffusion or to reduce the thickness of the transition layer formed. In FIG. 5B, the transition layer whose thickness is reduced by the formation of the diffusion layer 500 is indicated as a transition layer 700. A thickness of the transition layer 700 is changed depending on C concentration distribution, O concentration distribution or the like (in a thickness direction) of the diffusion layer 500. For example, by adjusting C content per unit area of the intermediate layer 400 as described below, the thickness of the transition layer 700 may be reduced or substantially eliminated (made to zero).

The transition layer 700 may also be said to be a layer whose etching rate is changed due to the diffusion of O into the second film 600 and whose etching rate is different from both the first film 300 and the second film 600.

Further, the intermediate layer 400 containing C also functions as a block layer (diffusion barrier layer) that suppresses the diffusion of O from the underlying first film 300 to the second film 600 in the second film formation step. This makes it possible to obtain an effect of further reducing the thickness of the transition layer 700.

Furthermore, in the second film formation step to be described later, the N-containing gas is activated by plasma excitation, and the second film 600, which is an N-containing film, is formed using the activated N-containing gas. At this time, since radicals and the like contained in the activated N-containing gas possess excessively high reactivity, at least a portion of C contained in the intermediate layer 400 may be desorbed from the intermediate layer 400 by these radicals and the like without being diffused into the second film 600. Furthermore, since the N-containing gas activated at this time is supplied from an outer edge (i.e., an outer region) toward the central region of the wafer 200, a larger amount of C is desorbed from the intermediate layer 400 in the outer region than in the central region in the substrate plane. In other words, an amount of C per unit area desorbed from the intermediate layer 400 differs between the central region and the outer region in the substrate plane, and an amount of C per unit area diffused into the second film 600 becomes smaller in the outer region than in the central region in the substrate plane.

More specifically, the outer region and the central region differ in at least one selected from the group of a thickness of the diffusion layer 500 and C content per unit area (e.g., C concentration) in the diffusion layer 500. For example, in this case, the thickness of the diffusion layer 500 may be thinner in the outer region and thicker in an inner region. Further, in this case, the C content per unit area (e.g., C concentration) in the diffusion layer 500 may be smaller in the outer region and larger in the central region.

Furthermore, since at least one selected from the group of the thickness of the diffusion layer 500 and the C content per unit area (e.g., C concentration) in the diffusion layer 500 is different between the central region and the outer region in the substrate plane, transition layer 700 with different etching rates between the central region and the outer region exhibits a varying thickness. More specifically, the thickness of the transition layer 700 in the outer region becomes thicker than the thickness of the transition layer 700 in the central region depending on at least one selected from the group of the thickness of the diffusion layer 500 and the C content per unit area (e.g., C concentration) in the diffusion layer 500. When the thickness of the transition layer 700 in the substrate plane becomes non-uniform in this way, at least a portion of the transition layer 700 is etched together with the first film 300 in the etching process for the first film 300, resulting in a thickness of the remaining second film 600 in the substrate plane to be non-uniform. Therefore, it is desirable that the thickness of the transition layer 700 be as thin as possible and be uniform in the substrate plane.

Therefore, according to the technique of the present disclosure, in the above-described intermediate layer formation step, the intermediate layer 400 is formed such that an amount of C per unit area in the intermediate layer 400 is different between the central region and the outer region in the substrate plane. For example, the intermediate layer 400 is formed such that the amount of C per unit area in the intermediate layer 400 is different at the center and at the outer edge (outer periphery) in the substrate plane. Specifically, the intermediate layer 400 is formed such that C content per unit area in the intermediate layer 400 is greater in the outer region than in the central region. By forming the intermediate layer 400 in this manner, even under a circumstance in the second film formation step in which C in the intermediate layer 400 in the outer region of the wafer 200 is more easily desorbed than C in the intermediate layer 400 in the central region of the wafer 200, a distribution of the amount of C per unit area diffused into the second film 600 (i.e., the C content of the diffusion layer 500 per unit area) in the substrate plane may be allowed to become a desired distribution in the second film formation step. As a result, a distribution of the thickness of the transition layer 700 in the substrate plane may also be allowed to become a desired distribution, for example, a uniform distribution. That is, by regulating an in-plane distribution of C content in the intermediate layer 400, it is possible to reduce variations in the thickness distribution of the transition layer 700, thus to perform regulations on the thickness distribution of the transition layer 700 to become nearly uniform, etc.

The distribution of the C content per unit area in the intermediate layer 400 may be regulated by, for example, regulating a thickness of the intermediate layer 400 in the substrate plane or C concentration in the intermediate layer 400 in the above-mentioned intermediate layer formation step.

For example, in this step, the intermediate layer 400 is formed so that the thickness of the intermediate layer 400 is different in the central region and the outer region in the substrate plane. Specifically, the intermediate layer 400 is formed such that the thickness of the intermediate layer 400 is greater in the outer region than in the central region in the substrate plane. By regulating the thickness of the intermediate layer 400, it is possible to control the distribution of C content per unit area in the substrate plane.

More specifically, in step S1a described above, the pressure in the process space (i.e., the process chamber 201) in which the wafer 200 is processed is set to be higher than a pressure at which the thickness of the intermediate layer 400 becomes uniform in the substrate plane. By increasing the pressure in the process space, a mean free path in the process space is reduced, promoting an adsorption of the precursor gas to the outer region in the substrate plane. Since a larger amount of precursor gas is adsorbed in the outer region than in the central region in the substrate plane, the thickness of the intermediate layer 400 in the outer region in the substrate plane may be regulated to be thicker than the thickness of the intermediate layer 400 in the central region. In other words, the thickness of the intermediate layer 400 may be regulated to exhibit a concave distribution in the substrate plane.

Further, in step S1a described above, the time for supplying the precursor gas is set to be shorter than time during which the thickness of the intermediate layer 400 becomes uniform in the substrate plane. By shortening the supply time of the precursor gas, an amount of the precursor gas that reaches the central region of the wafer 200 is reduced. As a result, the thickness of the intermediate layer 400 in the outer region in the substrate plane may be regulated to be thicker than the thickness of the intermediate layer 400 in the central region. In other words, the thickness of the intermediate layer 400 may be regulated to exhibit a concave distribution in the substrate plane.

Further, in step S1a described above, the flow rate of the inert gas supplied from the nozzle 249a simultaneously with the precursor gas and the flow rate of the inert gas supplied from the nozzle 249b are set to be greater than a flow rate of the inert gas at which the thickness of the intermediate layer 400 becomes uniform in the substrate plane. By increasing the flow rate of the inert gas supplied to the central region of the wafer 200, a partial pressure of the precursor gas supplied to the central region is reduced, and a partial pressure of the precursor gas supplied to the outer region is relatively increased. Thus, the thickness of the intermediate layer 400 in the outer region in the substrate plane may be regulated to be larger than the thickness of the intermediate layer 400 in the central region. In other words, the thickness of the intermediate layer 400 may be regulated to exhibit a concave distribution in the substrate plane.

An average thickness of the intermediate layer 400 in the substrate plane is desirably set to fall within a range of, for example, 7 to 35 Å, specifically 23 to 30 Å.

If the average thickness of the intermediate layer 400 in the substrate plane becomes less than 7 Å, it may be difficult to obtain the effect of reducing the thickness of the transition layer 700 formed in the second film formation step. By setting the average thickness of the intermediate layer 400 in the substrate plane to be 7 Å or more, it is possible to obtain the effect of reducing the thickness of the transition layer 700. By setting the average thickness of the intermediate layer 400 in the substrate plane to be 23 Å or more, the effect of reducing the thickness of the transition layer 700 may be more reliably obtained.

If the average thickness of the intermediate layer 400 in the substrate plane exceeds 35 Å, the amount of C per unit area diffused into the second film 600 becomes too large, which may make it difficult for the second film 600 to possess desired properties such as electrical properties and the like. By setting the average thickness of the intermediate layer 400 in the substrate plane to be 35 Å or less, it becomes easy to obtain the desired properties for the second film 600. By setting the average thickness of the intermediate layer 400 in the substrate plane to be 30 Å or less, it becomes easier to obtain the desired properties for the second film 600.

Further, a difference (also referred to as a deviation) in thickness between the center and the outer periphery (outer edge) in the substrate plane, i.e., between the central region and the outer region of the intermediate layer 400 in the substrate plane is, for example, 4 to 10 Å, specifically 5 to 8 Å. A magnitude of the deviation may be selected depending on a magnitude of a deviation of an amount of C desorbed from the intermediate layer 400 in the substrate plane in the second film formation step.

As described above, when the thickness of the intermediate layer 400 in the outer region in the substrate plane in step S1a is regulated to be thicker than the thickness of the intermediate layer 400 in the central region, it is preferable that a thickness of the second film 600 formed in the second film formation step to be described later is thicker in the central region than in the outer region in the plane of the wafer 200. As a result, a total thickness of a stacked film of the intermediate layer 400 and the second film 600 may be made uniform in the plane of the wafer 200.

Further, for example, in this step, the intermediate layer 400 is formed such that the C concentration in the intermediate layer 400 is different between the central region and the outer region in the substrate plane. In other words, the intermediate layer 400 is formed such that the C concentration in the intermediate layer 400 is higher in the outer region than in the central region in the substrate plane. By regulating the C concentration in the intermediate layer 400, it is possible to control the distribution of C content per unit area in the substrate plane.

Specifically, in step S1b described above, the pressure in the process space in which the wafer 200 is processed is set to be higher than a pressure at which the thickness of the C concentration in the intermediate layer 400 becomes uniform in the substrate plane. By regulating the pressure in the process space when supplying the C- and N-containing gas so as to increase the pressure in the process space, the mean free path in the process space is reduced, and an adsorption of the C- and N-containing gas at the outer region in the substrate plane is promoted. As a result, the C concentration in the intermediate layer 400 in the outer region may be regulated to be higher than the C concentration in the intermediate layer 400 in the central region.

Furthermore, in step S1b described above, the time for supplying the C and N-containing gas is set to be shorter than time during which the C concentration in the intermediate layer 400 becomes uniform in the substrate plane. By regulating the supply time of the C- and N-containing gas so as to shorten the supply time of the C- and N-containing gas, an amount of C- and N-containing gas that reaches the central region of the wafer 200 is reduced. As a result, the C concentration in the intermediate layer 400 in the outer region may be regulated to be higher than the C concentration in the intermediate layer 400 in the central region.

In step S1b described above, the flow rate of the inert gas supplied from the nozzle 249b simultaneously with the C- and N-containing gas and the inert gas supplied from the nozzle 249a is set to be higher than a flow rate of the inert gas at which the C concentration in the intermediate layer 400 becomes uniform in the substrate plane. By increasing the flow rate of the inert gas supplied toward the central region, a partial pressure of the C- and N-containing gas supplied to the central region is reduced, and a partial pressure of the C- and N-containing gas supplied to the outer region is relatively increased. As a result, the C concentration in the intermediate layer 400 in the outer region in the substrate plane may be regulated to be higher than the C concentration in the intermediate layer 400 in the central region.

It is desirable that an average C concentration in the intermediate layer 400 in the substrate plane is, for example, 3 to 15%, specifically 5 to 7%.

If the average concentration of C in the intermediate layer 400 in the substrate plane is less than 3%, it may be difficult to obtain the effect of reducing the thickness of the transition layer 700 formed in the second film formation step. By setting the average concentration of C in the intermediate layer 400 in the substrate plane to 3% or more, it is possible to obtain the effect of reducing the thickness of the transition layer 700. By setting the average concentration of C in the intermediate layer 400 in the substrate plane 5% or more, the effect of reducing the thickness of the transition layer 700 may be more reliably obtained.

If the average concentration of C in the intermediate layer 400 in the substrate plane exceeds 15%, the C content per unit area in the intermediate layer 400 becomes too large, which may make it difficult to obtain desired properties such as electrical properties and the like for the second film 600. By setting the average concentration of C in the intermediate layer 400 in the substrate plane to 15% or less, it becomes easy to obtain the desired properties for the second film 600. By setting the average concentration of C in the intermediate layer 400 in the substrate plane to 7% or less, it becomes easier to obtain the desired properties.

Further, a difference (also referred to as a deviation) in concentration between the center and the outer periphery (outer edge) in the substrate plane, i.e., between the central region and the outer region of the intermediate layer 400 in the substrate plane is, for example, 0.3 to 2.2%, specifically 0.7 to 1.8%. A magnitude of the deviation may be selected depending on a magnitude of a deviation of the amount of C desorbed from the intermediate layer 400 in the substrate plane in the second film formation step.

Further, by making a distribution of the thickness of the intermediate layer 400 uniform in an in-plane direction of the substrate while regulating the distribution of C concentration in the intermediate layer 400, it becomes easy to make the thickness of the stacked film of the intermediate layer 400 and the second film 600 uniform in the plane of the wafer 200.

After performing the intermediate layer formation step, a second film formation step is performed to form an N-containing layer that does not contain C by using plasma-excited N-containing gas. In the embodiments, a step of forming an N-containing layer that does not contain C (i.e., a C-free N-containing layer) on the intermediate layer 400 without using plasma excitation is not performed. In other words, after performing the intermediate layer formation step and before starting the second film formation step, the step of forming the N-containing layer that does not contain C on the intermediate layer 400 without using plasma excitation is not performed. As a result, the step of forming a C-free N-containing layer without using plasma excitation may be omitted, and productivity may be improved.

Furthermore, when forming the N-containing layer without using plasma excitation in the second film formation step, it may be needed to process the substrate at a higher processing temperature than both the intermediate layer formation step and the second film formation step. In other words, in order to form the N-containing layer using a thermally excited N-containing gas, a process for forming the N-containing layer may be performed at a higher temperature than when forming the N-containing layer using plasma excitation. By not performing the formation process of the N-containing layer using such thermal excitation, it is possible to suppress deterioration of device characteristics caused by thermal history. Furthermore, by not performing the N-containing layer formation process using such thermal excitation, from the start of the intermediate layer formation step to the end of the second film formation step, the temperature of the wafer 200 may be maintained at a temperature that does not exceed at least one selected from the group of the temperature of the wafer 200 in the intermediate layer formation step and the temperature of the wafer 200 in the second film formation step.

In this step, a distribution of C content per unit in the intermediate layer 400 is set such that the thickness of the transition layer 700 becomes a predetermined distribution in the substrate plane, for example, a uniform distribution, after performing the next second film formation step.

### (Second Film Formation Step)

Once the formation of the intermediate layer 400 is completed, the next two steps, namely steps S2a and S2b, are performed. That is, the second film 600 containing N is formed on the intermediate layer 400 using the N-containing gas activated by plasma excitation.

### [Step S2a]

In this step, a precursor gas is supplied to the wafer 200 in the process chamber 201, i.e., to the intermediate layer 400 formed on the first film 300. The processing procedure of this step is the same as the processing procedure of step S1a. An example of a processing condition for supplying the precursor gas in this step includes a processing temperature: room temperature (25degrees C.) to 550 degrees C., specifically 400 to 500 degrees C. Other processing conditions may be the same as those used when supplying the precursor gas in step S1a. In order to increase a deposition rate per film formation cycle of the second film 600, for example, at least one selected from the group of the supply flow rate and supply time of the precursor gas from the processing condition in step S2a may be set to be larger than in step S1a.

By performing step S2a, a Si-containing layer is formed on the intermediate layer 400 as a third layer.

### [Step S2b]

After step S2a is completed, an N-containing gas activated by plasma excitation is supplied to the wafer 200 in the process chamber 201, i.e., the third layer formed on the intermediate layer 400.

Specifically, the valve 243b is opened to allow the N-containing gas to flow into the gas supply pipe 232b. A flow rate of the N-containing gas is regulated by the MFC 241b. The N-containing gas is then supplied into the process chamber 201 via the gas supply pipe 232b and the nozzle 249b, plasma-excited in the buffer chamber 237, and exhausted from the exhaust pipe 231. At this time, the N-containing gas activated by plasma excitation is supplied to the wafer 200. At the same time, the valve 243e is opened to allow an inert gas to flow into the gas supply pipe 232e. A flow rate of the inert gas is regulated by the MFC 241e. The inert gas is then supplied into the process chamber 201 together with the N-containing gas.

A processing condition when supplying the N-containing gas in this step is exemplified as follows.
Processing pressure: 1 to 100 Pa
N-containing gas supply flow rate: 100 to 10,000 sccm
N-containing gas supply time (irradiation time): 1 to 120 seconds, specifically 1 to 60 seconds
Radio frequency power: 50 to 1,000 W
   Other processing conditions may be the same as those used when supplying the precursor gas in step S2a. The processing temperature in this step is specifically lower than that in step S2c in a modification described later.

By supplying the N-containing gas activated by plasma excitation to the wafer 200 under the above condition, it is possible to increase a formation speed of the second film 600 and to improve the productivity as compared with a case where an N-containing gas activated by thermal excitation is used. Furthermore, it may be easier to improve a film quality of the second film 600 and to reduce the processing temperature.

By supplying the activated N-containing gas to the wafer 200 under the above condition, at least a portion of the third layer is nitrided (modified). By modifying the third layer, a fourth layer, i.e., a layer containing a predetermined element and N and substantially free of O and C (i.e., an O- and C-free N-containing layer) is formed on the wafer 200, i.e., on the intermediate layer 400. When forming the fourth layer, impurities such as Cl contained in the third layer form a gaseous substance containing at least Cl and the like during the modifying reaction process by the N-containing gas. The impurities are discharged from the inside of the process chamber 201.

After the fourth layer is formed, the valve 243b is closed to stop the supply of the N-containing gas. Then, any unreacted N-containing gas or any N-containing gas after contributing to the formation of the fourth layer and reaction by-products, which remain in the process chamber 201, are removed from the inside of the process chamber 201 by the same processing procedure as in step S1a.

As the N-containing gas, for example, a hydrogen nitride-based gas such as an ammonia (NH₃) gas, a diazene (N₂H₂) gas, a hydrazine (N₂H₄) gas, an N₃H₈ gas or the like may be used. One or more of these gases may be used as the N-containing gas.

### (Performing a Predetermined Number of Times)

A cycle of performing the above-mentioned steps S2a and S2b non-simultaneously, i.e., without synchronization, is performed n times (where n is an integer greater than or equal to 1). Thus, the second film 600 containing a predetermined element and N may be formed on the intermediate layer 400. As the second film 600, for example, a SiN film containing Si as a predetermined element and N may be formed.

The second film 600 possesses higher etching resistance and lower etching rate than the first film 300. Further, the thickness of the second film 600 is thicker than the thickness of the intermediate layer 400. By making the thickness of the second film 600 thicker than the thickness of the intermediate layer 400, the second film 600 that does not include the diffusion layer 500 and does not contain C may be formed even after the second film formation step. The thickness of the second film 600 may be, for example, 15 to 500 Å, specifically 20 to 200 Å, and more specifically 30 to 100 Å.

As shown in FIG. 5B, in the second film formation step, the C element contained in the intermediate layer 400 is diffused into the second film 600. Therefore, a portion of the second film 600 containing diffused C and the intermediate layer 400 form the diffusion layer 500 containing C.

In this step, at least a portion of the C contained in the intermediate layer 400 is desorbed so that a distribution of the C content per unit area in the diffusion layer 500 after execution of this step becomes nearly uniform in the substrate plane.

As described above, in the second film formation step, at least a portion of C contained in the intermediate layer 400 is desorbed so that the thickness of the transition layer 700 exhibits a predetermined distribution, for example, becomes nearly uniform in the substrate plane.

That is, in the intermediate layer formation step, the intermediate layer 400 is formed so that the C content per unit area in the intermediate layer 400 is larger in the outer region than in the central region, and in the second film formation step, C is desorbed from the intermediate layer 400 such that the amount of C per unit area desorbed from the intermediate layer 400 is larger in the outer region than in the central region. In this case, a distribution of C content per unit area in the intermediate layer 400 formed in the intermediate layer formation step is set depending on a difference between the amount of C per unit area desorbed from the intermediate layer 400 in the central region in the substrate plane and the amount of C per unit area desorbed from the intermediate layer 400 in the outer region in the substrate plane in the second film formation step. As a result, the C content per unit area in the diffusion layer 500 after the second film formation step may be made nearly uniform in the substrate plane, enabling the thickness of the transition layer 700 to become nearly uniform in the substrate plane.

### (Purge Step/Atmospheric Pressure Restoration Step)

When the formation of the second film 600 is completed, an inert gas is supplied into the process chamber 201 from each of the gas supply pipes 232d and 232e, and is exhausted from the exhaust pipe 231. The inert gas acts as a purge gas. As a result, the inside of the process chamber 201 is purged, and gases and reaction by-products remaining in the process chamber 201 are removed from the inside of the process chamber 201 (purge). Thereafter, the atmosphere inside the process chamber 201 is replaced with the inert gas, and the pressure inside the process chamber 201 is returned to the atmospheric pressure.

### (Unloading Step)

Thereafter, the processed wafers 200 are unloaded from the lower end of the reaction tube 203 to an outside of the reaction tube 203 by the boat elevator 115 while being supported by the boat 217 (boat unloading). The processed wafers 200 are discharged from the boat 217 after they are unloaded to the outside of the reaction tube 203 (wafer discharging).

### (3) Etching Process

After the wafers 200 are unloaded from the process chamber 201, an additional film formation process, a resist pattern formation process, and the like are performed on the wafers 200 after the substrate processing. The wafers 200 subjected to these processes are then loaded into a reaction container provided in an etching apparatus. An etching process is performed on the first film 300 or the like formed on the surface of the wafer 200 by supplying an etching agent to the wafer 200 in the reaction tube while an inside of the reaction container is controlled to exhibit a predetermined processing pressure and processing temperature.

As the etching agent, an etching gas may be used. As the etching gas, for example, a fluorine-based gas such as a hydrogen fluoride (HF) gas or fluorine (F₂) gas, or a chlorine-based gas such as a hydrogen chloride (HCl) gas, diluted with an N₂ gas, may be used. One or more of these gases may be used as the etching gas. It may also be possible to use a mixture of these gases, add a H-containing gas (reducing gas) such as a H₂ gas to these gases, or activate these gases with plasma. In addition, as the etching agent, it may also be possible to use, for example, an etching solution such as an aqueous HF solution or an aqueous HCl solution, instead of the gaseous one.

### (4) Modifications

The substrate processing sequence in the embodiments is not limited to the embodiment shown in FIG. 4, and may be modified as in the following modifications.

### (Modification 1)

In this modification, step S2c, which is described below, is performed instead of step S2b of the second film formation step described above. That is, in the second film formation step described above, an N-containing gas is thermally activated by being thermally excited in a non-plasma state and is then supplied. A substrate processing sequence of this modification may also be denoted as follows.

(precursor gas→C- and N-containing gas)×m→(precursor gas→N-containing gas)×n=>second film/intermediate layer

In this modification, processing procedures and processing conditions in the intermediate layer formation step and step S2a of the second film formation step are respectively the same as those in the intermediate layer formation step and step S2a of the second film formation step in the substrate processing sequence shown in FIG. 4. Further, a processing procedure and a processing condition in step S2c are the same as those in step S2b except for the points described below. However, it is more preferable that at least the processing temperature from the processing condition in step S2a is the same as in step S2c.

### [Step S2c]

After step S2a is completed, the wafer 200 in the process chamber 201, i.e., the third layer formed on the intermediate layer 400, is supplied with the N-containing gas activated by heating (i.e., thermally excited).

Specifically, the valve 243b is opened to allow the N-containing gas to flow into the gas supply pipe 232b. A flow rate of the N-containing gas is regulated by the MFC 241b. The N-containing gas is then supplied into the process chamber 201 via the nozzle 249b, and is exhausted from the exhaust pipe 231. At the same time, the valve 243e is opened to allow an inert gas to flow into the gas supply pipe 232e. A flow rate of the inert gas is regulated by the MFC 241e. The inert gas is then supplied into the process chamber 201 together with the N-containing gas.

A processing condition when supplying the N-containing gas in this step is exemplified as follows.
Processing temperature: 250 to 700 degrees C., specifically 300 to 650 degrees C., more specifically 350 to 600 degrees C.
Processing pressure: 1 to 4,000 Pa, specifically 1 to 3,000 Pa
N-containing gas supply flow rate: 100 to 10,000 sccm
N-containing gas supply time: 1 to 120 seconds, specifically 1 to 60 seconds
   Other processing conditions may be the same as those used when supplying the precursor gas in the intermediate layer formation step. The processing temperature in this step is preferably higher than that in step S2b in the above-described embodiments.

By setting the pressure inside the process chamber 201 to such a relatively high pressure range, it becomes possible to thermally activate the N-containing gas in a non-plasma manner.

Also in this modification, the same effects as those of the above-described embodiments may be obtained. Furthermore, in this modification, by using the N-containing gas activated with thermal excitation, as compared with a case where the N-containing gas activated with plasma excitation, it may be easy to reduce the amount of C desorbed from the intermediate layer 400 in the second film formation step, thus reducing the deviation in the amount of desorption of C in the substrate plane.

In addition, even if the content of C per unit area in the intermediate layer 400 formed in the intermediate layer formation step is reduced, or even if the deviation in the content of C per unit area in the intermediate layer 400 formed in the intermediate layer formation step is reduced, it becomes easy to control the variation in the thickness of the transition layer 700 and its distribution after performing the second film formation step to a desired one.

### (Modification 2)

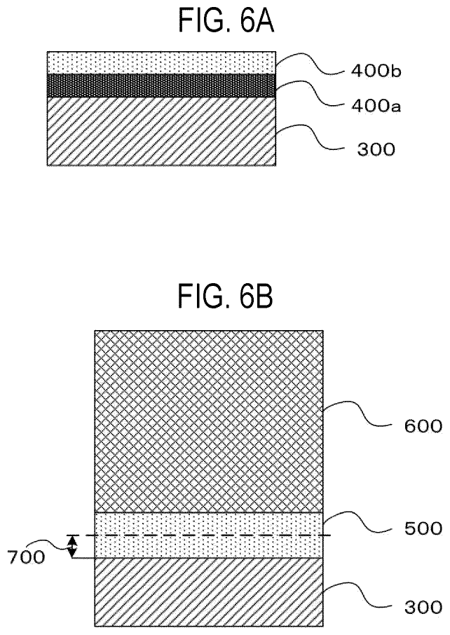

In this modification, as shown in FIG. 6A, after forming a first intermediate layer 400a containing C and N on the first film 300, a second intermediate layer 400b containing N, which is a cap layer and a thermally nitrided layer, is formed on the first intermediate layer 400a. The second intermediate layer 400b is, for example, a thermally nitrided SiN film. Then, a second film 600 is formed on the second intermediate layer 400b.

That is, after performing a first intermediate layer formation step in the same way as the intermediate layer formation step of the substrate processing sequence shown in FIG. 4 described above, a second intermediate layer formation step of thermally activating the N-containing gas is performed. That is, between the intermediate layer formation step and the second film formation step in the substrate processing sequence shown in FIG. 4 described above, a step similar to the second film formation step of modification 1 described above (but differing in the number of execution times of the cycle including steps S2a and S2c) is performed as the second intermediate layer formation step. That is, by using a N-containing gas thermally activated without using plasma excitation, the second intermediate layer 400b containing N, which possesses a lower C concentration than a C concentration in the first intermediate layer 400a, or substantially does not contain C, is formed on the first intermediate layer 400a. A substrate processing sequence of this modification may also be denoted as follows.

(precursor gas→C- and N-containing gas)×m→(precursor gas→N-containing gas)×p→(precursor gas→N-containing gas*)⇒second film/second intermediate layer/first intermediate layer

A processing procedure and a processing condition of the first intermediate layer formation step of forming the first intermediate layer 400a are respectively the same as the processing procedure and processing condition of the intermediate layer formation step in the substrate processing sequence shown in FIG. 4 described above. Further, a processing procedure and a processing condition of the second intermediate layer formation step of forming the second intermediate layer 400b are the same as the processing procedure and processing condition of the second film formation step (i.e., the thermal nitriding second film formation step) in modification 1 described above. Further, a processing procedure and a processing condition of the second film formation step of forming the second film 600 are the same as the processing procedure and processing condition of the second film formation step (i.e., the plasma nitriding second film formation step) in the substrate processing sequence shown in FIG. 4 described above.

Also in this modification, the same effects as those of the above-described embodiments may be obtained. Furthermore, in this modification, an amount of C desorbed from the first intermediate layer 400a may be further reduced in the second film formation step. That is, the second intermediate layer 400b may function as a cap layer that reduces or prevents desorption of C from the first intermediate layer 400a. By forming the second film 600 on the second intermediate layer 400b, a portion of C contained in the first intermediate layer 400a may be diffused into the second intermediate layer 400b. Specifically, as shown in FIG. 6B, for example, in the first intermediate layer 400a and the second intermediate layer 400b, the C-containing diffusion layer 500 may be formed as C is diffused into the second intermediate layer 400b during the formation of the second film 600. Furthermore, even if content of C per unit area in the first intermediate layer 400a formed in the first intermediate layer formation step is reduced, the thickness of the transition layer 700 after performing the second film formation step may be easily set to a desired thickness.

Furthermore, in the second intermediate layer formation step in this modification, the second intermediate layer 400b is formed such that, for example, a thickness of the second intermediate layer 400b is greater in the outer region than in the central region in the substrate plane. In this way, by making the effect of reducing or preventing desorption of C in the outer region higher than in the central region in the second film formation step, the transition layer 700 may be made uniform, for example, even in a case where the first intermediate layer 400a is formed to possess a uniform C content in the first intermediate layer 400a in the substrate plane. That is, in the second film formation step, when the amount of C desorbed in the outer region is larger than that in the central region, the amount of C desorbed from the first intermediate layer 400a may be adjusted to be nearly uniform in the substrate plane.

The thickness of the second intermediate layer 400b is specifically thinner than the thickness of the second film 600, and is, for example, 5 Å or more, specifically 10 Å or more, more specifically 15 Å or more, and still more specifically 20 Å or more.

If the thickness of the second intermediate layer 400b is less than 5 Å, it may be difficult to obtain the effect of reducing desorption of C from the first intermediate layer 400a in the second film formation step that uses plasma excitation. By setting the thickness of the second intermediate layer 400b to 5 Å or more, the effect of reducing desorption of C from the first intermediate layer 400a is obtained. Furthermore, by setting the thickness of the second intermediate layer 400b to 10 Å or more, the effect of reducing desorption of C from the first intermediate layer 400a may be more reliably obtained. Moreover, by setting the thickness of the second intermediate layer 400b to 15 Å or more, desorption of C from the first intermediate layer 400a may be substantially prevented. In addition, by setting the thickness of the second intermediate layer 400b to 20 Å or more, it is possible to obtain a more remarkable effect of preventing desorption of C from the first intermediate layer 400a.

In the first intermediate layer formation step, the first intermediate layer 400a may be formed such that a thickness of the first intermediate layer 400a is thicker in the outer region than in the central region in the substrate plane, and in the second intermediate layer formation step, the second intermediate layer 400b may be formed such that the thickness of the second intermediate layer 400b is thicker in the central region than in the outer region in the substrate plane. By doing so, when the first intermediate layer 400a is formed in a concave shape, the second intermediate layer 400b may be formed in a convex shape to improve the uniformity of the film thickness in the substrate plane. A total thickness of the first intermediate layer 400a and the second intermediate layer 400b may be made nearly uniform in the substrate plane.

### (Modification 3)

In this modification, in the intermediate layer formation step, a cycle of non-simultaneously performing a step of supplying a precursor gas to the wafer 200, a step of supplying a C-containing gas to the wafer 200, and a step of supplying an N-containing gas to the wafer 200 is performed a predetermined number of times (m1 times) to thereby form an intermediate layer 400 on the first film 300. That is, instead of the step of supplying the C- and N-containing gas in step S1b described above, a C-containing gas and a N-containing gas are supplied separately to thereby form a film containing a predetermined elements, C and N. In this case, each gas may be supplied individually by using a C-containing gas supply system and a N-containing gas supply system instead of the C- and N-containing gas supply system. Further, in this case, the N-containing gas supply system used in step S2b may be used as the N-containing gas supply system used in the intermediate layer formation step. A substrate processing sequence of this modification may also be denoted as follows.

(precursor gas→C-containing gas→N-containing gas)×m1→(precursor gas→N-containing gas*)×n1⇒second film/intermediate layer

In the step of supplying the C-containing gas, a supply flow rate of the C-containing gas is set to fall in a range of, for example, 100 to 10,000 sccm. The pressure inside the process chamber 201 is set to fall in a range of, for example, 1 to 5,000 Pa, specifically 1 to 4,000 Pa. Time for supplying the C-containing gas to the wafer 200 is, for example, 1 to 200 seconds, specifically 1 to 120 seconds, and more specifically 1 to 60 seconds. Other processing conditions are, for example, the same as those of the intermediate layer formation step in the above-described embodiments.

As the C-containing gas in this modification, for example, a hydrocarbon-based gas may be used. The hydrocarbon-based gas may also be said to be a substance composed of two elements, C and H. As the hydrocarbon-based gas, for example, a propylene (C₃H₆) gas or the like may be used. Further, as the C-containing gas in this modification, for example, a C- and N-containing gas may be used as in the above-described embodiments.

A processing procedure and a processing condition of the step of supplying the N-containing gas in the intermediate layer formation step are the same as those of step S2c in modification 1 described above. Further, a processing procedure and a processing condition of the step of supplying the precursor gas in the intermediate layer formation step and a processing procedure and a processing condition of the second film formation step are respectively the same as the processing procedures and processing conditions of the corresponding steps in the above-described embodiments.

Also in this modification, the same effects as in the above-described embodiments may be obtained. Further, in the intermediate layer formation step, the C-containing gas as a C source and the N-containing gas as an N source may be supplied to the wafer 200 as separate gases. Therefore, by regulating conditions for supplying the C-containing gas and the N-containing gas (e.g., supply flow rates, gas supply time, pressures during supply, and the like), it becomes easier to control the amount (e.g., concentration) of C and N contained in the intermediate layer.

### (Modification 4)

In this modification, different precursor gases are used in the intermediate layer formation step and the second film formation step of the substrate processing sequence described above. Substrate processing sequences in this modification may be denoted as follows.

(first precursor gas→C- and N-containing gas)×m→(second precursor gas→N-containing gas*)×n⇒second film/intermediate layer

(first precursor gas→C- and N-containing gas)×m→(second precursor gas→N-containing gas)×n⇒second film/intermediate layer

(first precursor gas→C-containing gas→N-containing gas)×m1→(second precursor gas→N-containing gas*)×n1⇒second film/intermediate layer

Further, in this modification, different precursor gases are used in the first intermediate layer formation step, the second intermediate layer formation step, and the second film formation step of the substrate processing sequences described above. A substrate processing sequence in this modification may be denoted as follows. Any two of the first to third precursor gases may be the same gas.

(first precursor gas→C- and N-containing gas)×m→(second precursor gas→N-containing gas)×p→(third precursor gas→N-containing gas*)⇒second film/second intermediate layer/first intermediate layer

Also in this modification, the same effects as those of the above-described embodiments may be obtained.

### Other Embodiments

Embodiments of the present disclosure are described above. However, the present disclosure is not limited to the above-described embodiments, and various modifications may be made without departing from the spirit of the present disclosure.

For example, in the above-described embodiments, the intermediate layer formation step and the second film formation step are continuously (in-situ) performed in the same process chamber 201. The present disclosure is not limited thereto, and the intermediate layer formation step and the second film formation step may be separately performed (ex-situ) in different process chambers (process containers). In this case, the same effects as those of the above-described embodiments may be obtained.

In the above-mentioned embodiments, the example in which the film is processed using the batch-type substrate processing apparatus that processes a plurality of substrates at a time is described. The present disclosure is not limited to the above-mentioned embodiments, and may be suitably applied to, for example, a case where a film is processed using a single-substrate type substrate processing apparatus that processes one or several substrates at a time. In addition, in the above-described embodiments, the example in which the film is processed using the substrate processing apparatus with the hot-wall type process furnace is described. The present disclosure is not limited to the above-mentioned embodiments, and may be suitably applied to, for example, a case where a film is processed using a substrate processing apparatus with a cold-wall type process furnace.

When using these substrate processing apparatuses, each process may be performed according to the same process procedures and under the same process conditions as in the above-described embodiments and modifications, and the same effects as in the above-described embodiments and modifications may be obtained.

The above-described embodiments and modifications may be used in appropriate combination. The processing procedures and processing conditions in this case may be the same as those of the above-described embodiments and modifications.

### EXAMPLE

The following describes experimental results that support the effects obtained in the above-described embodiments and modifications. The processing condition in each step of preparing evaluation samples were set to fall within the range of processing condition in each step of the above-described embodiments.

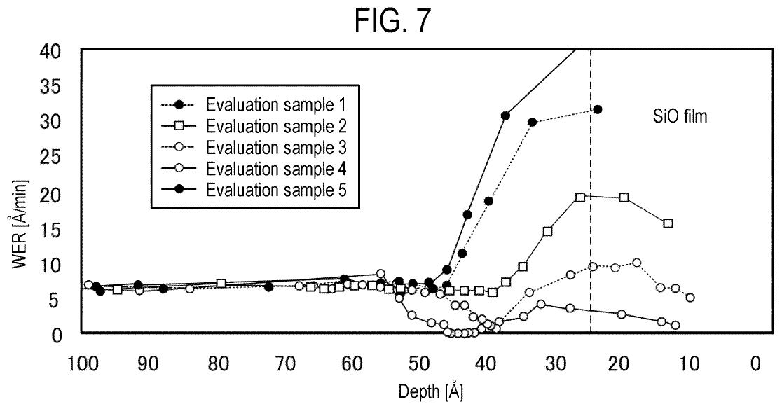

FIG. 7 shows evaluation results of etching resistance (processing resistance) of evaluation samples 1 to 5 which are films differing in the thickness of the intermediate layer 400.

In evaluation samples 1 to 4, by using the substrate processing apparatus of the above-described embodiments, a SiCN layer was formed as an intermediate layer on a SiO film formed on a substrate surface, and a plasma-nitrided SiN film was formed on the SiCN layer according to the substrate processing sequence shown in FIG. 4. In evaluation samples 1 to 4, thicknesses of the SiCN layer were set to 2 Å, 4 Å, 6 Å, and 7 Å, respectively.

In evaluation sample 5, by using the substrate processing apparatus of the above-described embodiments, a plasma-nitrided SiN film was formed on a SiO film formed on a substrate surface by forming a thermally nitrided SiN layer with a thickness of 23 Å on the first film without performing the intermediate layer formation step of the substrate processing sequence shown in FIG. 4, and then performing the second film formation step.

Then, the etching resistance (processing resistance) was measured for each of the films of evaluation samples 1 to 5. FIG. 7 is a diagram showing a depth profile of a wet etching rate (WER) when the film of each evaluation sample was etched using a 1% HF aqueous solution. The vertical axis in FIG. 7 indicates the WER (Å/min) of each film (layer). The horizontal axis in FIG. 7 indicates a total thickness (Å) of each film (layer). An interface between the SiO film and the SiCN layer is located in the range of 20 to 25 (Å) on the horizontal axis.

Referring to FIG. 7, it may be seen that the change in WER (change in etching resistance) of the films of evaluation samples 3 and 4 is smaller than the change in WER (change in etching resistance) of the films of evaluation samples 1, 2 and 5. In other words, it may be seen that a width (thickness) of a transition layer of evaluation samples 3 and 4 is thinner than a width (thickness) of a transition layer of evaluation samples 1, 2 and 5. That is, it was confirmed that the thickness of the transition layer is possible to be reduced by making the thickness of the intermediate layer relatively large, and that the thickness of the transition layer is possible to be regulated by regulating the thickness of intermediate layer 400.

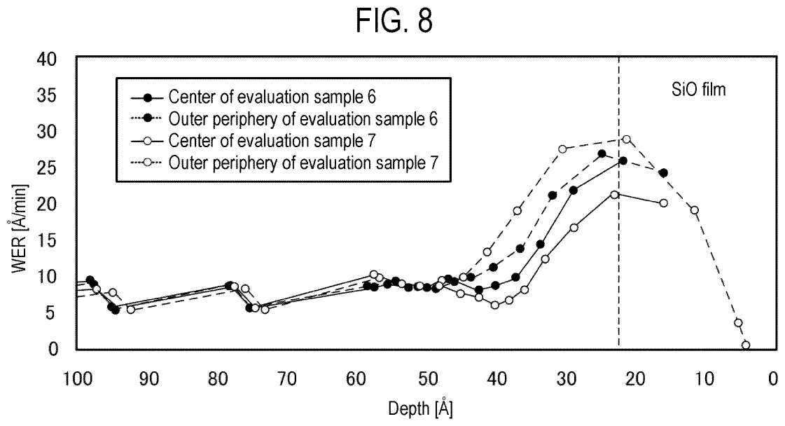

FIG. 8 shows evaluation results of etching resistance (processing resistance) of films of evaluation samples 6 and 7 on a center and an outer periphery of a substrate.

In evaluation sample 6, by using the substrate processing apparatus of the above-described embodiments, a SiCN layer was formed as an intermediate layer on a SiO film formed on a substrate surface, and a SiN film was formed on the SiCN layer according to the substrate processing sequence shown in FIG. 4. In evaluation sample 6, the SiCN layer was formed so that the thickness thereof is thicker in an outer region than in a central region in a substrate plane.

In evaluation sample 7, by using the substrate processing apparatus of the above-described embodiments, a SiCN layer was formed as an intermediate layer on a SiO film formed on a substrate surface, and a SiN film was formed on the SiCN layer according to the substrate processing sequence shown in FIG. 4. In evaluation sample 7, the SiCN layer was formed to possess a uniform thickness in a substrate plane.

Then, the etching resistance (processing resistance) of the film on the substrate surface on the center and the etching resistance (processing resistance) of the film on the substrate surface on the outer periphery in evaluation sample 6 and evaluation sample 7 were measured.

FIG. 8 is a diagram showing the WER when the films of evaluation samples 6 and 7 are etched using a 1% HF aqueous solution. The vertical axis in FIG. 8 indicates the WER (Å/min) of the film. The horizontal axis in FIG. 8 indicates a total thickness (Å) of each film (layer). An interface with the SiO film is located in the range of 20 to 25 (Å) on the horizontal axis.

As shown in FIG. 8, it may be seen that a WER difference between the center and the outer periphery of the substrate is smaller in the film with a differing in-plane film thickness distribution of evaluation sample 6 than in the film with a uniform in-plane film thickness distribution of evaluation sample 7. In other words, it was confirmed that the WER difference between the center and the outer periphery in the substrate plane may be made smaller when forming the intermediate layer to possess a differing in-plane film thickness distribution than when forming the intermediate layer to possess a uniform in-plane film thickness distribution.

According to the present disclosure, it is possible to suppress an occurrence of a change in properties such as an etching resistance and the like which may occur in an interface between a base and a film when the film is formed, or to control a thickness distribution of a transition layer in a plane of a substrate even when the transition layer is formed.

While certain embodiments are described, these embodiments are presented by way of examples, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) forming an intermediate layer containing carbon on a first film formed on the substrate; and
(b) forming a second film containing nitrogen on the intermediate layer by using an activated nitrogen-containing gas,
wherein in (a), the intermediate layer is formed such that a carbon content per unit area in the intermediate layer differs between a central region and an outer region in a substrate plane of the substrate.

2. The method of claim 1, wherein in (a), the intermediate layer is formed such that the carbon content per unit area in the intermediate layer is greater in the outer region than in the central region.

3. The method of claim 1, wherein in (a), the intermediate layer is formed such that a thickness of the intermediate layer differs between the central region and the outer region.

4. The method of claim 1, wherein in (a), the intermediate layer is formed such that a thickness of the intermediate layer is greater in the outer region than in the central region.

5. The method of claim 4, wherein in (b), the second film is formed such that a thickness of the second film is greater in the central region than in the outer region.

6. The method of claim 1, wherein in (a), the intermediate layer is formed such that a concentration of carbon contained in the intermediate layer differs between the central region and the outer region.

7. The method of claim 1, wherein in (a), the intermediate layer is formed such that a concentration of carbon contained in the intermediate layer is greater in the outer region than in the central region.

8. The method of claim 1, wherein in (b), at least a part of the carbon contained in the intermediate layer is desorbed from the intermediate layer.

9. The method of claim 1, wherein in (b), the carbon is desorbed from the intermediate layer such that an amount of carbon desorbed per unit area from the intermediate layer differs between the central region and the outer region.

10. The method of claim 1, wherein in (a), the intermediate layer is formed such that the carbon content per unit area in the intermediate layer is greater in the outer region than in the central region, and
wherein in (b), the carbon is desorbed from the intermediate layer such that an amount of carbon desorbed per unit area from the intermediate layer is greater in the outer region than in the central region.

11. The method of claim 1, wherein after (b) is performed, a transition layer having an etching resistance different from an etching resistance of both the first film and the second film is formed between the first film and the second film, and
wherein in (a), a distribution of the carbon content per unit area in the intermediate layer is set such that a thickness of the transition layer has a predetermined distribution in the substrate plane.

12. The method of claim 1, wherein in (b), the activated nitrogen-containing gas is supplied from the outer region toward the central region.

13. The method of claim 1, wherein in (b), the nitrogen-containing gas is activated by plasma excitation.

14. The method of claim 1, wherein in (b), the nitrogen-containing gas is thermally activated by heating.

15. The method of claim 1, wherein after (a) is performed and before (b) is started, forming a carbon-free nitrogen-containing layer on the intermediate layer without using plasma excitation is not performed.

16. The method of claim 1, wherein in (b), the nitrogen-containing gas activated by plasma excitation is used, and
wherein the method further comprises:
(c) between (a) and (b), forming a nitrogen-containing second intermediate layer on the intermediate layer by using a nitrogen-containing gas thermally activated without using plasma excitation, the second intermediate layer having a lower carbon concentration than a carbon concentration in the intermediate layer or being carbon-free.

17. The method of claim 16, wherein in (c), the second intermediate layer is formed such that a thickness of the second intermediate layer is greater in the outer region than in the central region.

18. A method of manufacturing a semiconductor device, comprising the method of claim 1.

19. A non-transitory computer-readable recording medium storing a program that causes, by a computer, a substrate processing apparatus to perform a process comprising:
(a) forming an intermediate layer containing carbon on a first film formed on a substrate; and
(b) forming a second film containing nitrogen on the intermediate layer by using an activated nitrogen-containing gas,
wherein in (a), the intermediate layer is formed such that a carbon content per unit area in the intermediate layer differs between a central region and an outer region in a substrate plane of the substrate.

20. A substrate processing apparatus, comprising:
a carbon-containing gas supply system configured to supply a carbon-containing gas to a substrate;
a nitrogen-containing gas supply system configured to supply a nitrogen-containing gas to the substrate;
an activator configured to activate the nitrogen-containing gas; and
a controller configured to be capable of controlling the carbon-containing gas supply system, the nitrogen-containing gas supply system and the activator to perform a process including:
(a) forming an intermediate layer containing carbon on a first film formed on the substrate by supplying the carbon-containing gas to the substrate; and
(b) forming a second film containing nitrogen on the intermediate layer by supplying an activated nitrogen-containing gas to the substrate,
wherein in (a), the intermediate layer is formed such that a carbon content per unit area in the intermediate layer differs between a central region and an outer region in a substrate plane of the substrate.
